(19) United States
(12) Patent Application Publication
(10) Pub. No.: US 2014/0159706 A1
(43) Pub. Date: Jun. 12, 2014

(54) TRANSVERSE ELECTROMAGNETIC CELL

(71) Applicant: Electronics and Telecommunications Research Institute, Daejeon (KR)

(72) Inventors: Sang Bong JEON, Daejeon (KR); Seung Keun PARK, Daejeon (KR)

(73) Assignee: Electronics and Telecommunications Research Institute, Daejeon (KR)

(21) Appl. No.: 13/967,653

(22) Filed: Aug. 15, 2013

(30) Foreign Application Priority Data
Dec. 11, 2012 (KR) 10-2012-0143973

(51) Int. Cl. G01R 33/00

(52) U.S. Cl. CPC G01R 33/0076
USPC 324/201

(57) ABSTRACT

A TEM cell includes an untapered region part configured to have a straight-line structure in which a cross-sectional area of an internal space is constantly maintained, tapered region parts coupled between both sides of the untapered region part and a connection part and each configured to have a tapered structure in which the cross-sectional area of the internal space is reduced toward the connection part, wherein a horizontal length of the tapered region part and a horizontal length of the untapered region part are determined in such a way as to reduce an electromagnetic field component in a direction vertical to a cross section of the untapered region part. The EMS evaluation performance of the TEM cell can be improved because an unnecessary electromagnetic field component can be reduced by designing the horizontal length of the untapered region longer than the horizontal length of the tapered region.

### CROSS-REFERENCE(S) TO RELATED APPLICATION(S)

The present application claims priority under 35 U.S.C 119(a) to Korean Application No. 10-2012-0143973, filed on Dec. 11, 2012, in the Korean Intellectual Property Office, which is incorporated herein by reference in its entirety set forth in full.

### BACKGROUND

An exemplary embodiment of the present invention relates to a Transverse ElectroMagnetic (TEM) cell, and more particularly, to a TEM cell capable of improving the evaluation performance of ElectroMagnetic Susceptibility (EMS) by reducing an unnecessary electromagnetic field component within the TEM cell.

With the recent rapid growth of electrical and electronic devices, unintentional and unnecessary electromagnetic waves are increasing and the influence of external electromagnetic waves on IT devices driven by low power is also increasing. Accordingly, there is a need for a tighter Electromagnetic compatibility evaluation method in order to implement a safe radio environment.

Electromagnetic compatibility evaluation is commonly performed in a wide and open area test site having a relatively good radio environment, but an Electromagnetic compatibility evaluation device capable of replacing the Electromagnetic compatibility evaluation in a wide and open area test site has been in the spotlight due to problems, such as securing a location for a test site and necessary expenses.

In particular, a TEM cell is a representative electromagnetic wave test device. International Electrotechnical Commission (IEC) has established the standards of requirements for the TEM cell and continues to manage the standards.

More particularly, the TEM cell generates standard electromagnetic waves by using the characteristic of the TEM cell that generates low impedance electromagnetic waves (i.e., a magnetic field) at a point where pieces of power are met in phase and generates high impedance electromagnetic waves (i.e., an electric field) at a point where the pieces of power have a phase difference of 180°, within a coupled transmission line when the pieces of power are transmitted in opposite directions.

EMS measurement, ElectroMagnetic Interference (EMI) measurement, the correction of an electromagnetic probe, and measurement for the sensitivity of a radio device are performed by using the standard electromagnetic waves generated from the TEM cell.

The TEM cell is divided into a tapered region and an untapered region. In general, the tapered region and the untapered region of the existing TEM cell are designed to have the same horizontal length. If the TEM cell is configured as described above, there is a problem in that an unnecessary electromagnetic field component in unwanted directions can be generated.

That is, the existing TEM cell is problematic in that the accuracy of EMS evaluation can be deteriorated due to a distribution of unnecessary electromagnetic waves in addition to a distribution of intentional electromagnetic waves for the EMS evaluation.

A related prior art includes Korean Patent Laid-Open Publication No. 1996-0010759 (Jan. 1, 1999) entitled ‘THE UPPER OPENING AND SHUTTING TYPE TEM CELL’.

### SUMMARY

An embodiment of the present invention relates to a TEM cell capable of improving the evaluation performance of EMS by reducing an unnecessary electromagnetic field component other than a distribution of intentional electromagnetic waves within the TEM cell.

In one embodiment, a TEM cell includes an untapered region part configured to have a straight-line structure in which a cross-sectional area of an internal space is constantly maintained, tapered region parts coupled between both sides of the untapered region part and a connection part and each configured to have a tapered structure in which the cross-sectional area of the internal space is reduced toward the connection part, wherein a horizontal length of the tapered region part and a horizontal length of the untapered region part are determined in such a way as to reduce an electromagnetic field component in a direction vertical to a cross section of the untapered region part.

In the present invention, the horizontal length of the untapered region part is longer than the horizontal length of the tapered region part.

In the present invention, the horizontal length of the untapered region part is determined based on electric field strength experiment values of the electromagnetic field component.

In the present invention, the experiment values are measured while increasing the horizontal length of the untapered region part in a state in which the horizontal length of the tapered region part is fixed.

In the present invention, a cross section of the internal space has a rectangle.

### BRIEF DESCRIPTION OF THE DRAWINGS

The above and other aspects, features and other advantages will be more clearly understood from the following detailed description taken in conjunction with the accompanying drawings, in which:

FIG. 1 is a front cross-sectional view schematically showing a structure of a TEM cell in accordance with an embodiment of the present invention;

FIG. 2 is a side cross-sectional view schematically showing a structure of the TEM cell in accordance with an embodiment of the present invention;

FIG. 3 is a plan cross-sectional view schematically showing a shape of the TEM cell seen from the top in accordance with an embodiment of the present invention;

FIG. 4 is a graph showing a change of electric field strength in an x-axis direction according to a change in the horizontal length of an untapered region in relation to the TEM cell in accordance with an embodiment of the present invention;

FIG. 5 is a graph showing a change of electric field strength in a y-axis direction according to a change in the horizontal length of the untapered region in relation to the TEM cell in accordance with an embodiment of the present invention; and

FIG. 6 is a graph showing a change of electric field strength in a z-axis direction according to a change in the horizontal length of the untapered region in relation to the TEM cell in accordance with an embodiment of the present invention.

### DESCRIPTION OF SPECIFIC EMBODIMENT

Hereinafter, a TEM cell in accordance with an embodiment of the present invention will be described with reference to accompanying drawings. However, the embodiment is for illustrative purposes only and is not intentional to limit the scope of the invention.

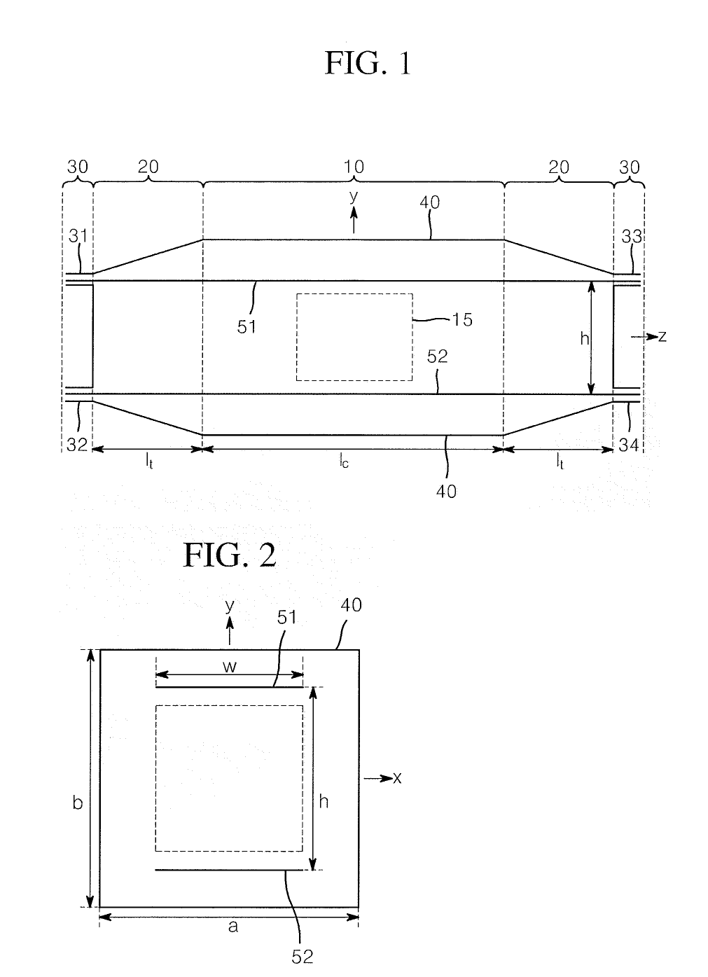

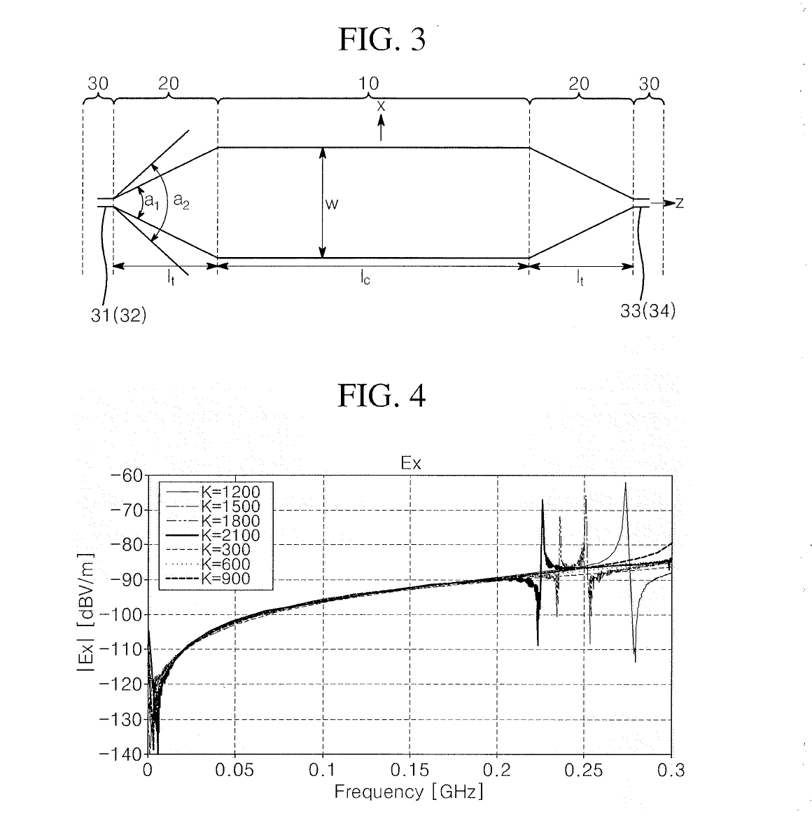

FIG. 1 is a front cross-sectional view schematically showing a structure of a TEM cell in accordance with an embodiment of the present invention, FIG. 2 is a side cross-sectional view schematically showing a structure of the TEM cell in accordance with an embodiment of the present invention, and FIG. 3 is a plan cross-sectional view schematically showing a shape of the TEM cell seen from the top in accordance with an embodiment of the present invention.

In general, the TEM cell is a lot used as an EMS measurement device because it can provide an environment in which EMS evaluation is possible irrespective of an external radio environment. The TEM cell can be basically classified into a 1-port TEM cell, a 2-port TEM cell, and a 4-port TEM cell.

The 1-port TEM cell has an advantage in that it can perform measurement up to a GHZ region, but has a limit to the occurrence of a near field because it has one port.

Meanwhile, the 2-port and 4-port TEM cells have an advantage in that the occurrence of a near field is possible although measurable frequencies are limited. In particular, the 4-port TEM cell is being widely used because it has more advantages than the 2-port TEM cell in terms of the occurrence of a near field.

As shown in FIG. 1, the TEM cell in accordance with an embodiment of the present invention can be formed of a 4-port TEM cell. The TEM cell can include an untapered region part 10, tapered region parts 20, and a connection part 30.

Referring to FIG. 1, the untapered region part 10 and the tapered region parts 20 are configured to have an internal space by external conductors 40, and first and second internal conductors 51 and 52 are formed within the untapered region part 10 and the tapered region parts 20.

Referring to FIG. 2, a cross section of the internal space formed by the untapered region part 10 and the tapered region parts 20 can be a rectangle having a horizontal length ‘a’ and a vertical length ‘b’, but not limited thereto. For example, a cross section of the internal space may have other forms, such as a circle.

The untapered region part 10 corresponds to a region in which an Equipment Under Test (EUT) is placed. As shown in FIG. 1, the untapered region part 10 can have a straight-line structure in which a cross-sectional area of the internal space is constantly maintained. Referring to FIGS. 1 and 2, the EUT can be placed in a specific location within a test space 15 between the first internal conductor 51 and the second internal conductor 52.

The tapered region parts 20 correspond to regions in which the untapered region part 10 is coupled with the connection part 30. Referring to FIGS. 1 and 3, each of the tapered region parts 20 can have a tapered structure in which a cross-sectional area of the internal space is decreased from the untapered region part 10 toward the connection part 30.

The sizes ‘a’ and ‘b’ of the external conductors 40 or the width ‘w’ and the height ‘h’ of the first and the second internal conductors 51 and 52, forming the untapered region part 10 and the tapered region parts 20, may be properly selected according to an impedance matching condition.

Meanwhile, a distribution of electromagnetic waves within the untapered region part 10 varies depending on the horizontal length ‘l_{c}’ of the untapered region part 10 and the horizontal length ‘lₜ’ of the tapered region part 20.

In the present invention, the horizontal length ‘l_{c}’ of the untapered region part 10 and the horizontal length ‘lₜ’ of the tapered region part 20 are determined in such a way as to reduce an unnecessary electromagnetic field component in a direction vertical to the cross sections of the untapered region part 10 and the tapered region parts 20 (i.e., a z-axis direction in FIGS. 1 and 3).

To this end, the horizontal length ‘l_{c}’ of the untapered region part 10 is determined based on electric field strength experiment values of an unnecessary electromagnetic field component in the z-axis direction.

A method of determining the horizontal length ‘l_{c}’ of the untapered region part 10 and the horizontal length ‘lₜ’ of the tapered region part 20 based on the electric field strength experiment values of an unnecessary electromagnetic field component in the z-axis direction as described above is described in detail with reference to FIGS. 4 to 6.

The connection part 30 includes one or more connection terminals to which an external cable is connected.

Referring to FIGS. 1 and 3, in the 4-port TEM cell in accordance with the present embodiment, the connection part 30 can include first and second connection terminals 31 and 32 and third and fourth connection terminals 33 and 34 disposed on both sides of the untapered region part 10 and spaced apart from each other at a specific interval.

The first connection terminal 31 and the third connection terminal 33 can be disposed so that they are coupled with the first internal conductor 51 on a straight line, and the second connection terminal 32 and the fourth connection terminal 34 can be disposed so that they are coupled with the second internal conductor 52 on a straight line.

A method of determining the horizontal length ‘l_{c}’ of the untapered region part 10 based on electric field strength experiment values is described in detail below with reference to FIGS. 4 to 6.

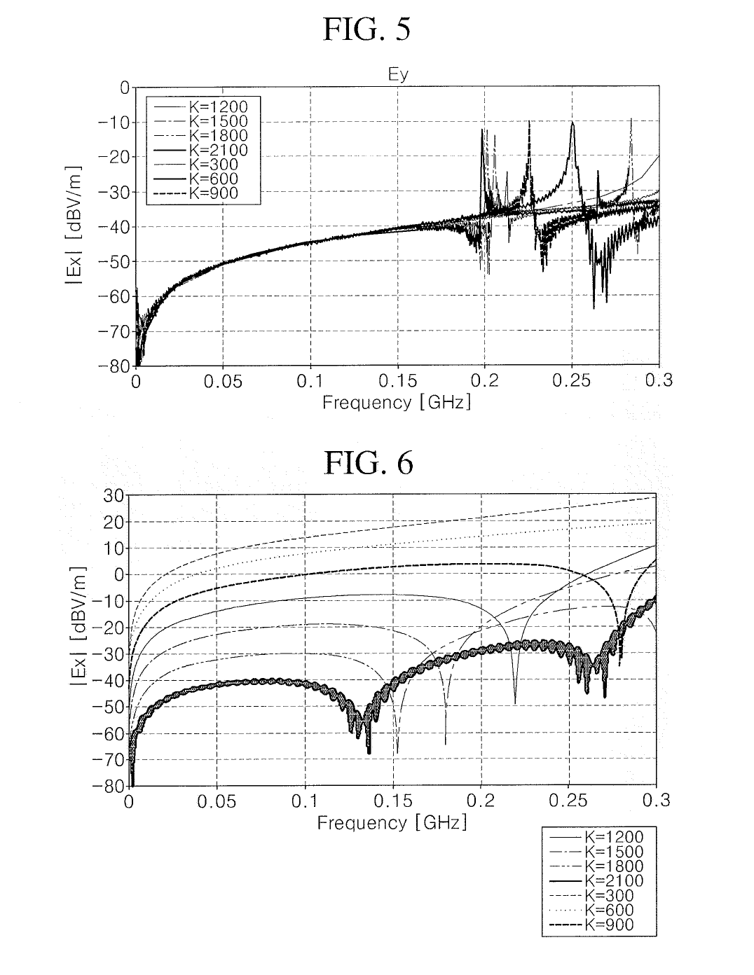

FIG. 4 is a graph showing a change of electric field strength in an x-axis direction according to a change in the horizontal length of an untapered region in relation to the TEM cell in accordance with an embodiment of the present invention, FIG. 5 is a graph showing a change of electric field strength in a y-axis direction according to a change in the horizontal length of the untapered region in relation to the TEM cell in accordance with an embodiment of the present invention, and FIG. 6 is a graph showing a change of electric field strength in a z-axis direction according to a change in the horizontal length of the untapered region in relation to the TEM cell in accordance with an embodiment of the present invention.

As described above, in the 4-port TEM cell in accordance with an embodiment of the present invention, the horizontal length ‘l_{c}’ of the untapered region part 10 is determined based on the electric field strength experiment values of an unnecessary electromagnetic field component in the internal space. Here, the experiment values can be values measured while increasing the horizontal length ‘l_{c}’ of the untapered region part 10 with the horizontal length ‘lₜ’ of the tapered region part 20 being fixed.

For example, a change in the electric field strength of an electromagnetic field component within the internal space of the TEM cell can be measured while increasing the horizontal length of the untapered region part 10 1 to 7 times (i.e., from 300 mm to 2100 mm) greater than the horizontal length ‘lₜ’ of the tapered region part 20 in the state in which the horizontal length ‘lₜ’ of the tapered region part 20 is fixed to 300 mm. Results of the measurement are shown in FIGS. 4 to 6.

Meanwhile, referring to FIGS. 1 to 3, electromagnetic field components in the x-axis and y-axis directions correspond to field components necessary for the EMS evaluation of a EUT, and an electromagnetic field component in the z-axis direction corresponds to an unintentional and unnecessary field component.

That is, in accordance with the present embodiment, the horizontal length ‘l_{c}’ of the untapered region part 10 suitable for reducing an unnecessary electromagnetic field component can be derived by comparing a change of pieces of electric field strength Ex and Ey in the x-axis and y-axis directions, that is, intentional field components, with electric field strength Ez in the z-axis direction corresponding to an unintentional and unnecessary electromagnetic field component.

From FIGS. 4 and 5, it can be seen that the pieces of electric field strength Ex and Ey in the x-axis and y-axis directions are rarely changed although the horizontal length ‘l_{c}’ of the untapered region part 10 is increased in a resonant frequency or lower.

In contrast, from FIG. 6, it can be seen that the electric field strength Ez in the z-axis direction corresponding to an unintentional and unnecessary electromagnetic field component is decreased as the horizontal length ‘l_{c}’ of the untapered region part 10 is increased.

More particularly, when the horizontal length ‘l_{c}’ of the untapered region part 10 is 600 mm, in a frequency of 100 MHz, the electric field strength Ez in the z-axis direction is reduced by about 6 dB as compared with a case where the horizontal length l_{c}' of the untapered region part 10 is 300 mm.

Likewise, when the horizontal length ‘l_{c}’ of the untapered region part 10 is 900 mm, the electric field strength Ez in the z-axis direction is reduced by about 8 dB as compared with a case where the horizontal length ‘l_{c}’ of the untapered region part 10 is 600 mm. Furthermore, when the horizontal length ‘l_{c}’ of the untapered region part 10 is 1200 mm, the electric field strength Ez in the z-axis direction is reduced by about 9 dB as compared with a case where the horizontal length l_{c}' of the untapered region part 10 is 900 mm. Subsequently, the electric field strength Ez in the z-axis direction is converged while being reduced to 10 dB.

A decrement of the electric field strength Ez in the z-axis direction according to a change in the horizontal length ‘l_{c}’ of the untapered region part 10 when a frequency is 75 MHz, 100 MHz, and 125 MHz is shown in Table 1 below.

TABLE 1

| | Frequency | | | | | |
|---|---|---|---|---|---|---|
| | 75 [MHz] | | 100 [MHz] | | 125 [MHz] | |
| lc | Ez | Decrement | Ez | Decrement | Ez | Decrement |
| [mm] | [dB] | [dB] | [dB] | [dB] | [dB] | [dB] |
| 300 | 11.2 | — | 13.8 | — | 15.9 | — |
| 600 | 5.4 | 5.8 | 7.8 | 6.0 | 9.6 | 6.3 |
| 900 | −2.6 | 8.0 | −0.3 | 8.1 | 1.3 | 8.3 |
| 1200 | −11.0 | 8.4 | −9.4 | 9.1 | −8.4 | 9.7 |
| 1500 | −20.4 | 9.4 | −19.3 | 9.9 | −19.3 | 10.9 |
| 1800 | −30.3 | 9.9 | −30.0 | 10.7 | −32.1 | 12.8 |
| 2100 | −40 | 9.7 | −40.7 | 10.7 | −55.9 | 23.8 |

In a TEM cell, if the horizontal length ‘l_{c}’ of the untapered region part 10 and the horizontal length ‘lₜ’ of the tapered region part 20 are configured to be the same, a high frequency region can be covered and a wide test space 15 can be secured, but there is a disadvantage in that an unnecessary electromagnetic field component is increased.

In particular, if electric field strength in an unnecessary direction is greatly generated, it is difficult to produce near field electromagnetic wave mode. Accordingly, an unnecessary electromagnetic field component corresponding to a direction in which electromagnetic waves travel should not be present in order to produce a near field distribution.

In accordance with the present invention, what a stabilized near field can be generated and an electromagnetic field in an unnecessary direction can be reduced when the horizontal length ‘l_{c}’ of the untapered region part 10 corresponds to what the horizontal length ‘lₜ’ of the tapered region part 20 is analyzed through experiments, and horizontal length of the untapered region part 10 is determined based on a result of the experiments.

As described above, in accordance with the present invention, an unnecessary electromagnetic field component can be reduced by designing the horizontal length ‘l_{c}’ of the untapered region part 10 longer than the horizontal length ‘lₜ’ of the tapered region part 20. Accordingly, the EMS evaluation performance of the TEM cell can be improved.

Meanwhile, in the present embodiment, the resonant frequency is illustrated as being lowered as the horizontal length ‘l_{c}’ of the untapered region part 10 increases. However, a detailed description of technology in which the resonant frequency is extended is omitted because the technology can be incorporated into the present invention when a TEM cell is designed based on a known art.

In accordance with the present invention, the EMS evaluation performance of the TEM cell can be improved because an unnecessary electromagnetic field component can be reduced by designing the horizontal length of the untapered region longer than the horizontal length of the tapered region.

The embodiment of the present invention has been disclosed above for illustrative purposes. Those skilled in the art will appreciate that various modifications, additions and substitutions are possible, without departing from the scope and spirit of the invention as disclosed in the accompanying claims.

What is claimed is:

1. A Transverse ElectroMagnetic (TEM) cell, comprising:
an untapered region part configured to have a straight-line structure in which a cross-sectional area of an internal space is constantly maintained;
tapered region parts coupled between both sides of the untapered region part and a connection part and each configured to have a tapered structure in which the cross-sectional area of the internal space is reduced toward the connection part,
wherein a horizontal length of the tapered region part and a horizontal length of the untapered region part are determined in such a way as to reduce an electromagnetic field component in a direction vertical to a cross section of the untapered region part.

2. The TEM cell of claim 1, wherein the horizontal length of the untapered region part is longer than the horizontal length of the tapered region part.

3. The TEM cell of claim 1, wherein the horizontal length of the untapered region part is determined based on electric field strength experiment values of the electromagnetic field component.

4. The TEM cell of claim 3, wherein the experiment values are measured while increasing the horizontal length of the untapered region part in a state in which the horizontal length of the tapered region part is fixed.

5. The TEM cell of claim 1, wherein a cross section of the internal space has a rectangle.
